(19) United States
(12) Patent Application Publication
(10) Pub. No.: US 2025/0370165 A1
(43) Pub. Date: Dec. 4, 2025

(54) METHOD OF MANUFACTURING OPTICAL COMPONENTS

(71) Applicant: KOIDE JAPAN LTD., TOCHIGI (JP)

(72) Inventors: RYUICHI KIMURA, TOCHIGI (JP); TAKEKI NAKADA, TOCHIGI (JP); TSUTOMU KURIHARA, TOCHIGI (JP); YASUHIRO SEKINE, TOCHIGI (JP)

(73) Assignee: KOIDE JAPAN LTD., TOCHIGI (JP)

(21) Appl. No.: 19/107,286

(22) PCT Filed: Aug. 25, 2023
(86) PCT No.: PCT/JP2023/030759

§ 371 Date: Feb. 27, 2025

(30) Foreign Application Priority Data
May 1, 2023 (JP) 2023-075695

(51) Int. Cl. G02B 1/12; C23C 14/02; C23C 14/10; C23C 14/24

(52) U.S. Cl. CPC G02B 1/12; C23C 14/022; C23C 14/10; C23C 14/24

(57) ABSTRACT

Through the formation of a protective film on a fine uneven structure formed on a surface of a synthetic resin substrate, an optical component with a high anti-reflection effect under a high temperature environment is produced. The method for producing an optical component according to the present disclosure includes a fine uneven structure forming step of changing a surface of a substrate by ion irradiation, so as to form a fine uneven structure on the substrate surface, and a protective film forming step of evaporating and depositing a deposition material on the surface of the substrate, so as to form a protective film on the fine uneven structure formed on the surface of the substrate.

### DESCRIPTION

### Technical Field

The present disclosure relates to a method for producing an optical component, and is, for example, applicable to a method for manufacturing an optical component having a high anti-reflection effect under a high temperature environment, which involves forming a protective film on a fine uneven structure formed on the surface of a plastic (synthetic resin) substrate.

### Background Art

Well-translucent plastic is lightweight and excellent in mechanical strength, has good workability, and can be freely designed, and thus is used particularly as an alternate material for glass. Plastic is used particularly in the optical field. In recent years, plastic has been used for wide-ranging parts such as car headlights.

Examples of clear plastic that is currently used in many cases include thermoplastic polyvinyl chloride (PVC), polystyrene (PS), polycarbonate (PC), poly methyl methacrylate (PMMA), and thermosetting polyethylene glycol bis-allyl carbonate (CR39).

Of these plastics, PMMA is excellent in transparency, lightweightness, ease of processing, shock resistance, etc., as an optical component, and particularly its luminous transmittance is the best compared to other resins.

### CITATION LIST

### Patent Literature

### PATENT LITERATURE 1: Japanese Unexamined Patent Application Publication No. 2019-015826

### SUMMARY OF INVENTION

### Technical Problem

However, when an anti-reflection film for suppressing surface reflection is formed on a surface of a PMMA substrate in order to improve the transparency of an optical component produced using poly methyl methacrylate (PMMA), there are problems as follows.

For example, because a reliability condition of about 70° C. is required for consumer electronics such as projectors in the optical field, an anti-reflection film can be deposited on the surface of a PMMA substrate by vacuum evaporation. On the other hand, a reliability condition for illumination systems in the automotive field is that such a system can withstand high temperatures ranging from 90° C. to 100° C. (hereinafter, “high-temperature environment” refers to an environment at about 90° C. to 100° C.). Accordingly, there is a problem such that because of a difference between the coefficient of linear expansion of a substrate and the coefficient of linear expansion of an anti-reflection film, cracking etc., occur on the deposited anti-reflection film.

Further, regarding car headlights, a single lens was initially used, but car headlights with higher precision which are produced with multiple lenses, are being demanded. The use of multiple lenses is problematic in that aberration correction is required to increase the number of lenses, along which surface reflection is also increased.

In view of the above problems, in order to achieve heat resistance under a target high temperature condition and to prevent the loss of light quantity, an object of the present disclosure is to provide a method for manufacturing an optical component having a high anti-reflection effect under a high temperature environment, which involves forming a protective film on a fine uneven structure formed on a surface of a substrate made of a synthetic resin such as poly methyl methacrylate.

### Solution to Problem

In order to solve such problems, the method for manufacturing an optical component according to the present disclosure involves (1) a fine uneven structure forming step of changing a surface of a substrate by ion irradiation, so as to form a fine uneven structure on the substrate surface, and (2) a protective film forming step of evaporating and depositing a deposition material on the substrate surface, so as to form a protective film on the fine uneven structure formed on the substrate surface.

### Advantageous Effects of Invention

According to the present disclosure, a protective film is formed on a fine uneven structure formed on a surface of a synthetic resin substrate, and thus an optical component having an anti-reflection effect under a high temperature environment can be manufactured.

### BRIEF DESCRIPTION OF DRAWINGS

FIG. 1 depicts conditions for the formation of fine uneven structures in step A and the spectral characteristics of substrates having the fine uneven structures.

FIG. 2 depicts conditions for the formation of fine uneven structures in step C and the spectral characteristics of substrates having the fine uneven structures.

FIG. 3 depicts the spectral characteristics of substrates having fine uneven structures and protective films formed in the steps of Example 1.

FIG. 4 depicts the spectral characteristics of substrates having fine uneven structures and protective films formed in the steps of Example 2.

FIG. 5 depicts the spectral characteristics of substrates having fine uneven structures and protective films formed in the steps of Example 3.

FIG. 6 depicts the spectral characteristics of substrates having fine uneven structures and protective films formed in the steps of Example 4.

FIG. 7 depicts the spectral characteristics of substrates having fine uneven structures and protective films formed in the steps of Example 5.

FIG. 8 depicts the results obtained using substrates having fine uneven structures formed in Step A, specifically, the spectral characteristics of the substrates before a high temperature test and the spectral characteristics of the substrates under a high temperature environment.

FIG. 9 depicts the results obtained using the substrates of Example 1, specifically the spectral characteristics before a high temperature test, and the spectral characteristics under a high temperature environment.

FIG. 10 depicts the results obtained using the substrates of Example 3, specifically, the spectral characteristics before a high temperature test, and the spectral characteristics under a high temperature environment.

FIG. 11 depicts the results of comparing the anti-reflection effect of Example 1 with that of other anti-reflection films.

FIG. 12 depicts the spectral characteristics of Example 1 and those of other anti-reflection films.

### DESCRIPTION OF EMBODIMENTS

### (A) Embodiment Hereinafter, the embodiment of the method for manufacturing an optical thin film of the present disclosure will be described in detail with reference to drawings.

### (A-1) Overview

In recent years, a demand for plastic optical components has been increased as an alternate for glass optical components. For example, a method is known in which involves forming a fine uneven structure on a surface of a substrate in order to prevent the surface reflection of optical lens.

One of such fine uneven structures is the one referred to as the moth-eye (this is called “moth-eye” since it mimics fine protrusions present over the surface of moth eyes.) structure. In the present disclosure, the moth-eye structure is exemplified as an example of the fine uneven structure, but the examples thereof are not limited to the moth-eye structure.

A conventional example of a method for forming the moth-eye structure on a surface of a plastic substrate is a method that involves molding a fine uneven structure by injection molding using a metal mold.

However, this method is problematic in that when a molded product is removed from a metal mold, a resin adheres to the metal mold, and this may cause the fine uneven structure to deform. Hence, it is difficult to employ the method as a method for producing such a product.

Another example thereof is a method that uses ion sputtering. Ion sputtering is a phenomenon that is caused by ion irradiation, and is a method that involves subjecting a surface of a PMMA substrate to ion irradiation which modifies the surface and causing a deformation of the shape of the surface. Conventionally, for example, a plasma gun is mounted in a vacuum deposition device, and then ion irradiation is performed during deposition to activate evaporated molecules, so as to improve the film strength.

The inventors of the present application have confirmed that a PMMA substrate subjected to ion irradiation without depositing (lamination) a multi-layer film on a surface of the substrate forms a moth-eye shape (the shape having a fine uneven structure) on its surface, thereby confirming the anti-reflection effect and the spectral characteristics of the PMMA substrate having the moth-eye shape.

PMMA is composed of molecules bonded to form the chain, and the C—O moiety of C—OOCH3 is cleaved by plasma, thereby forming the moth-eye shape. Indeed, through the use of a plasma gun with reference to the technique, by adjusting conditions including argon gas flow rate, oxygen flow rate, and ion irradiation electric power, a moth-eye shape could be formed on the substrate surface. Moreover, with the use of another technique CVD (chemical vapor deposition (CVD) device), the moth-eye could also be formed by a plasma discharge by adjusting argon gas flow rate, oxygen flow rate, and high frequency AC power. The formation of fine uneven structures on the substrate surfaces made it possible to confirm the anti-reflection effect or the effect of the spectral characteristics of reflection reducing optical coating.

However, when a test was conducted under a high temperature environment as required in the automotive field, the spectral characteristics were changed to result in the original surface reflection of the lens, and the purpose could not be attained. This is because the moth-eye shape; that is a fine uneven structure, loses its shape under a high temperature environment.

Therefore, as a result of intensive studies, the inventors of the present application propose that a conventional anti-reflection film made of a multilayer film is not deposited (lamination) on a substrate, but instead a thin protective film is formed on a fine uneven structure shape (for example, moth-eye shape) on the surface of a synthetic resin substrate to such an extent that no stress occurs on the film (protective film).

As a result, this made it possible to maintain the fine uneven structure shape under a high temperature environment, improve the heat resistance of the optical component, and confirm anti-surface reflection function and spectral characteristics.

The protective film maintained the fine uneven structure to improve heat resistance. A material of the protective film is desirably silicon oxide having a refractive index lower than that of the synthetic resin of a substrate. A high refractive index leads to increased reflection due to light interference. Accordingly, a material having a moderate refractive index is desired, for example, a material having a refractive index of 1.6 or less is preferred and further a material having a refractive index of 1.65 or less is desired. When irradiation is performed at a wavelength of 550 nm, the protective film desirably has an optical film thickness of λ/50 to λ/16.

The protective film functions as an anti-reflection film that suppresses the reflection of a surface of a substrate, and in addition has spectral characteristics of (optical) demultiplexing light wavelength. Further, the protective film functions as a film that maintains the shape of the fine uneven structure even under a high temperature environment. In the present disclosure, a case wherein the protective film is a silicon oxide (SiO₂) film or a silicon oxide mixed (SiOx) film is exemplified, but the examples thereof are not limited thereto.

### (A-2) Method for Manufacturing Optical Thin Film

Hereinafter, the method for producing an optical thin film according to the embodiment will be described.

The method for manufacturing an optical thin film according to the embodiment involves forming a fine uneven structure on a surface of a substrate by ion irradiation, and then forming a protective film on the fine uneven structure on the substrate surface.

### (1) Substrate

A substrate to be used herein is a plastic substrate (clear substrate) made of plastic (synthetic resin) excellent in transparency as a material. As plastic for the clear substrate, polymethyl methacrylate (PMMA), which is excellent in transparency and is formed of molecules bound to form the chain), is used.

The present disclosure utilizes the characteristics of PMMA such that the surface is changed by surface modification of the substrate due to ion irradiation, and then a moth-eye shape is formed on the substrate surface. Accordingly, a synthetic resin to be used herein is not limited to PMMA as long as a fine uneven structure is formed on a surface by ion irradiation, and other synthetic resins can be widely used.

Note that the use of polycarbonate (PC) having a benzene ring, and Cycro Olefin Polymer (COP) that is a cyclic compound results in no fine uneven structure shape formed by ion irradiation on a substrate surface, and thus they are difficult to be used as substrates.

### (2) Material (Deposition Material)

A material is desired to have a refractive index lower than that of plastic (synthetic resin) to be used for a substrate. The use of a synthetic resin having a high refractive index as a material for the substrate may result in reflection increased by light interference.

In this embodiment, silicon oxide is used as a material (deposition material). Note that an example of such a material (deposition material) is not limited to silicon oxide, and for example, aluminum oxide, titanium oxide, tantalum oxide, zirconium oxide and the like may also be used.

### (3) Formation Method

Examples of a method for forming a protective film on a surface of a substrate include generally (a) a method that involves directly depositing silicon oxide as a material, and (b) a method that involves forming a Si+SiO₂+SiO mixed film material (hereinafter, referred to as “SiOx”) on the substrate by subjecting hexamethyldisiloxane (HMDS) to a plasma discharge (polymerization).

### (3-1) Previous Step

First, when a fine uneven structure is formed on a substate, pure water and a neutral detergent are added to an ultrasonic cleaner, and then the substrate is placed in the cleaner for ultrasonic cleaning, since dirt such as burnt or faded portions, fingerprints, and oil may be present on a surface of the substrate. Moreover, since PMMA has a high coefficient of water absorption, the substrate is desirably pre-dried.

### (3-2) Setting Substrate in Vacuum Device

After the completion of the above-described previous step, a substrate is set in a vacuum device. Here, an exhaust system of the vacuum device is not particularly limited, and for example, vacuum pumps, such as a diffusion pump and a turbo molecular pump can be used.

Regarding devices to be used for the method for forming an optical thin film, a case of using one of or both a vacuum evaporator mounted with a plasma gun and a chemical vapor deposition device is exemplified.

When a vacuum evaporator mounted with a plasma gun is used, possible steps are “Step A” of forming a fine uneven structure on a surface of a substrate, and “Step B” of forming a protective film on the fine uneven structure on the substrate surface.

Similarly, when a chemical vapor deposition device is used, possible steps are “Step C” of forming a moth-eye shape on a surface of a substrate and “step D” of forming a protective film on the moth-eye shape on the substrate surface.

In the following examples (Examples 1 to 5), of “Step A” to “Step D”, effective steps can be combined.

Detailed descriptions therefor will be given later. Depending on a combination of the steps, examples of such a method include a method that involves forming a “moth-eye shape” and a “protective film” using both a vacuum evaporator and a chemical vapor deposition device, and a method that involves forming a “moth-eye shape” and a “protective film” using a vacuum evaporator or a chemical vapor deposition device.

In other words, the former method (specifically, the method using two devices) can be described as a method that involves forming the “moth-eye shape” and the “protective film” in two stages.

Conversely, the latter method (specifically, the method using one device) can be described as a method that involves forming the “moth-eye shape” and the “protective film” in one stage. Specifically, this method enables to proceed the steps successively with one device, and thus is expected to improve the productivity of optical components and perform efficient production.

(3-3) Vacuum Evaporator Mounted with Plasma Gun

The vacuum evaporator mounted with a plasma gun generally includes a vacuum chamber, a substrate set part (rack) for setting a substrate in the vacuum chamber, a deposition source provided with a crucible for setting a material as a deposition material, an electron gun, a plasma gun, a heater for heating a substrate, and a vacuum pump as an exhaust system.

### [Step A]

A substrate is set in a rack in such a manner that a surface thereof faces a deposition source, and a material as a deposition material is set in a crucible. Subsequently, after reducing pressure within the vacuum chamber by the use of a vacuum pump, the substrate is heated by a heater as necessary. Then the evaporated and sublimed material substance (deposition substance) is subjected to ion irradiation by the use of a plasma gun within the vacuum chamber, so as to change the shape of the substrate surface, and to form a fine uneven structure shape on the substrate surface. Specifically, a moth-eye shape is formed on the substrate surface. This step is referred to as “Step A”. According to Step A, a substance is activated by ion irradiation, so as to improve the film strength.

Note that the evaporation and sublimation of a deposition substance are not essential. In Examples 1 to 5 exemplified in the embodiment, a case of not performing evaporation and sublimation of a deposition substance is exemplified.

### [Step B]

A substrate is set in a rack in such a manner that a surface thereof faces a deposition source, and a material as a deposition material is set in a crucible. Subsequently, after reducing pressure within the vacuum chamber by the use of a vacuum pump, the substrate is heated by a heater as necessary. Up to this point, the procedure is the same as a portion of Step A.

Next, the deposition substance is dissolved using an electron gun within the vacuum chamber for evaporation, the evaporated deposition material is deposited on the substrate surface, and then a protective film is formed on the substrate surface. This step is referred to as “Step B”.

### (3-4) Chemical Vapor Deposition (CVD) Device

The chemical vapor deposition device generally includes a reaction chamber, a substrate set part for setting a substrate in the reaction chamber, a high frequency power source, a material supply part for supplying a material gasified by discharging plasma using high frequency to the reaction chamber, a supply part for supplying a gas (carrier gas) to the reaction chamber, and a vacuum pump as an exhaust system for evacuating the reaction chamber.

### [Step C]

A substrate is set in a substrate set part, and a material is set in a material supply part. Subsequently, a reaction chamber is evacuated by a vacuum pump, and then a gas is supplied by a supply part in such a manner that the gas is guided to flow from the supply part to the vacuum pump within the reaction chamber. Then, plasma is generated using high frequency (for example, 36.56 MHz), the material supply part supplies the evaporated material into the reaction chamber, and then a fine uneven structure shape is formed on the surface of the substrate. This step is referred to as “Step C”.

Here, the type of gas to be supplied by the supply part to the reaction chamber can be an argon gas, an oxygen gas, a nitrogen gas, etc.

### [Step D]

A substrate is set in a substrate set part, and a material is set in a material supply part. Subsequently, a reaction chamber is evacuated using a vacuum pump, a gas is supplied by a supply part in such a manner that the gas is guided to flow from the supply part to the vacuum pump within the reaction chamber. Up to this point, the procedure is the same as a portion of Step C.

Next, a plasma discharge is generated using high frequency in the material supply part, organic silicon such as hexamethyldisiloxane (HMDS), tetraethoxysilane (TEOS), or triethoxysilane (TRIES) is gasified, the material gasified using high frequency is polymerized to form SiOx. Then the material supply part supplies SiOx into the reaction chamber, so as to form a protective film on a surface of the substrate. This step is referred to as “Step D”.

### (3-5) Conditions for Formation of Fine Uneven Structure Onto Substrate Surface

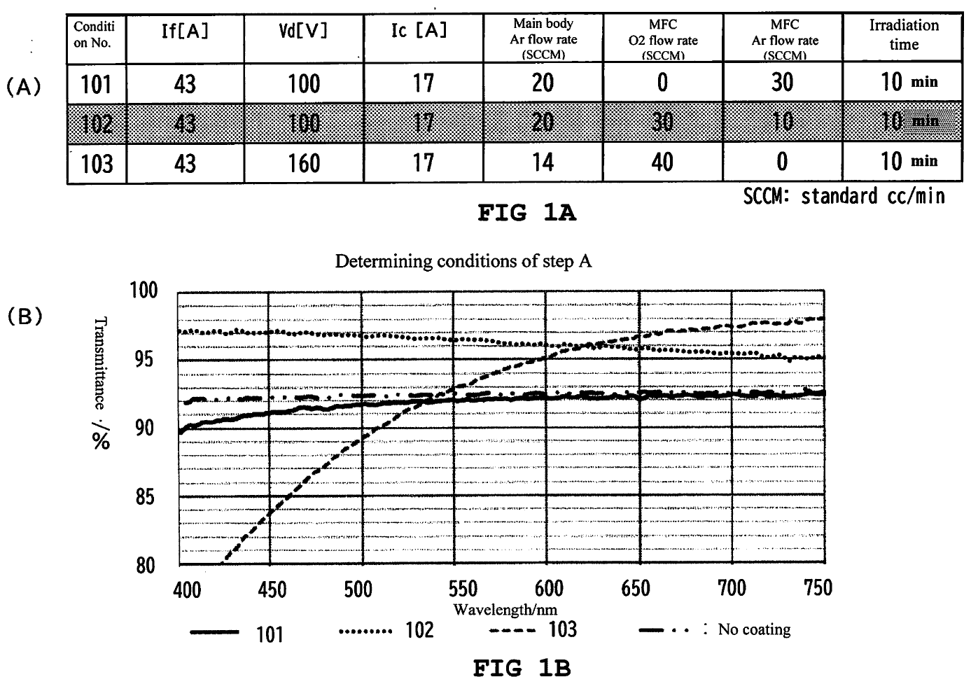

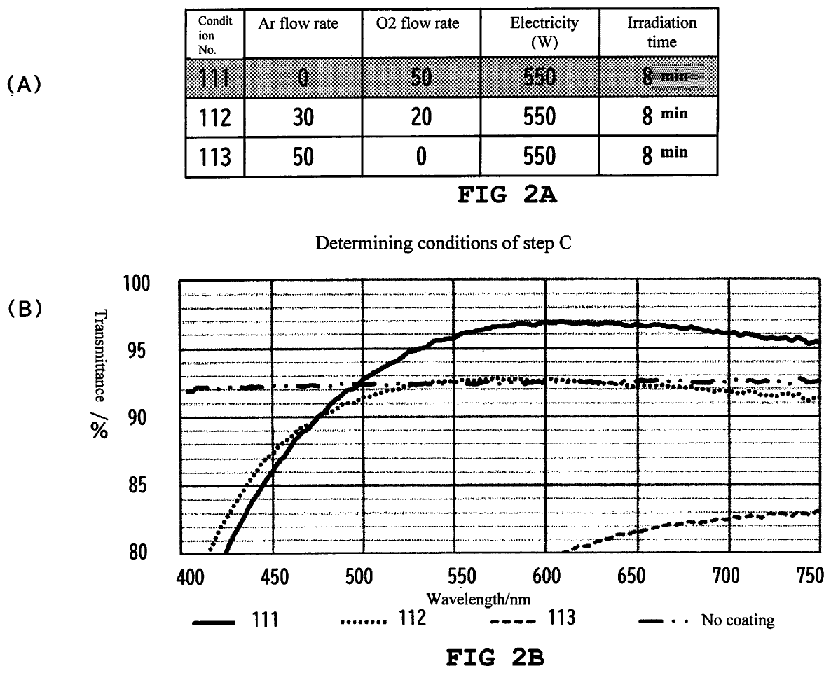

Conditions for the formation of a fine uneven structure shape on a surface of a substrate in “Step A” and the same in “Step C” are described with reference to FIG. 1 and FIG. 2.

FIG. 1(A) depicts conditions for the formation of a fine uneven structure by Step A, and FIG. 1(B) depicts the results of confirming the transmission property of a substrate having a fine uneven structure under each type of condition.

In FIG. 1(B), the horizontal axis indicates wavelength [nm] and the vertical axis indicates transmittance [%]. While wavelength (λ) was varied from 400 nm to 750 nm, a substrate transmitted light, thereby confirming the transmittance at each wavelength.

As in FIG. 1(B), the results of condition No. 102 were good such that a transmittance of about 95% to 97% was maintained at each wavelength between 400 nm and 750 nm. Accordingly, in Examples and Comparative Examples below, upon formation of a fine uneven structure on a substrate surface in Step A, the structure was formed under the conditions of condition No. 102.

FIG. 2(A) depicts conditions for the formation of a fine uneven structure by Step C, and FIG. 2(B) depicts the results of confirming the transmission property of a substrate having a fine uneven structure under each type of condition.

As understood from FIG. 2(B), the results of condition No. 111 were such that a high transmittance was maintained at each wavelength between 400 nm and 750 nm, and particularly, a transmittance of about 90% to 97% was maintained with respect to particularly light having a wavelength between 470 nm and 750 nm. Accordingly, in Examples and Comparative Examples, fine uneven structures were formed on the surfaces of the substrates under the conditions of condition No. 111.

### (A-3) Description of Examples

### (A-3-1) Example 1 (Step A+Step B)

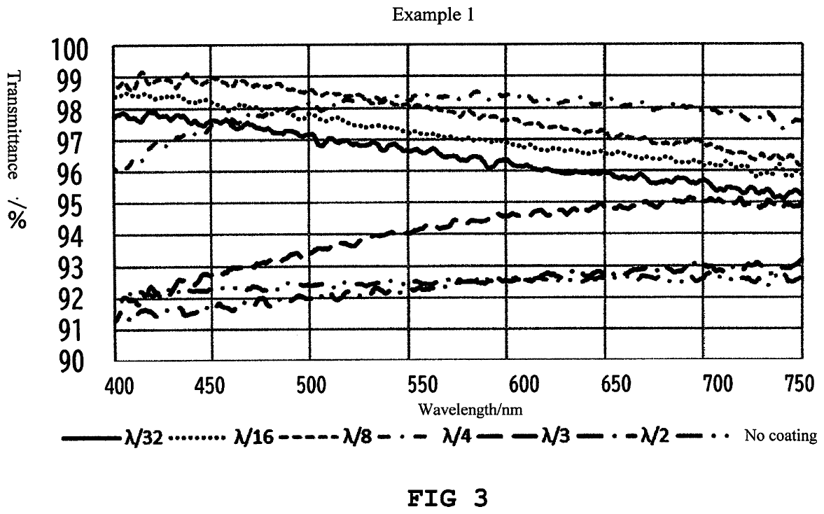

FIG. 3 depicts the spectral characteristics of substrates having fine uneven structures and protective films formed in the steps of Example 1. The steps of Example 1 are a combination of Step A and Step B.

In Step A, a substrate was set in a rack of a vacuum evaporator, a vacuum chamber was evacuated using a vacuum pump to have an atmospheric pressure of 5×10⁻³(5E−3) Pa within the vacuum chamber, and then ion irradiation was performed. Note that the vacuum evaporator used herein was a dome vacuum chamber having a device diameter (the diameter of the vacuum chamber) of 1600ϕ.

In Step B, the vacuum evaporator in Step A was used. Specifically, SiO₂ as a material was evaporated using an electron gun without opening the vacuum chamber, thereby depositing an SiO₂ film on the substrate surface.

In Example 1, with varied optical film thicknesses of SiO₂ to be deposited on the substrate surface, each sample substrate was irradiated with light having each wavelength between 400 nm and 750 nm, and then the transmission property was measured.

Conditions for the SiO₂ film were determined in such a manner that the optical film thicknesses were λ/32, λ/16, λ/8, λ/4, λ/3, and λ/2, when a light wavelength λ of 550 nm was used for irradiating the substrates. These 6 substrates and those having no SiO₂ deposited thereon (no coating) were used as samples.

As understood from the results of FIG. 3, each of all substrates having an optical film thickness of λ/32 to λ/2 (λ/32, λ/16, λ/8, λ/4, λ/3, λ/2) at each wavelength between 400 nm and 750 nm exhibited a transmittance of about 90% or more, and maintained a high transmittance.

As understood from FIG. 3, of these 6 substrates, each of substrates having λ/32 to λ/3 (λ/32, λ/16, λ/8, λ/4, λ/3) maintained a transmittance of about 92% or more with respect to light having each wavelength between 470 nm and 750 nm, and had a good anti-reflection effect, and, furthermore, each of substrates having λ/32 to λ/4 (λ/32, λ/16, λ/8, λ/4) maintained a transmittance of about 95% to 99%, and had a high anti-reflection effect.

Moreover, it was found that of these 6 substrates, each of substrates having λ/3 and λ/2 tended to exhibit a higher transmittance as the value of the wavelength was increased.

Further, it was found that of these 6 substrates, each of substrates having λ/32 to λ/3 (λ/32, λ/16, λ/8, λ/4, λ/3) exhibited a high transmittance with respect to light having each wavelength between 470 nm and 750 nm, and tended to exhibit a high transmittance with respect to a wavelength lower than 550 nm.

### (A-3-2) Example 2 (Step A+Step D)

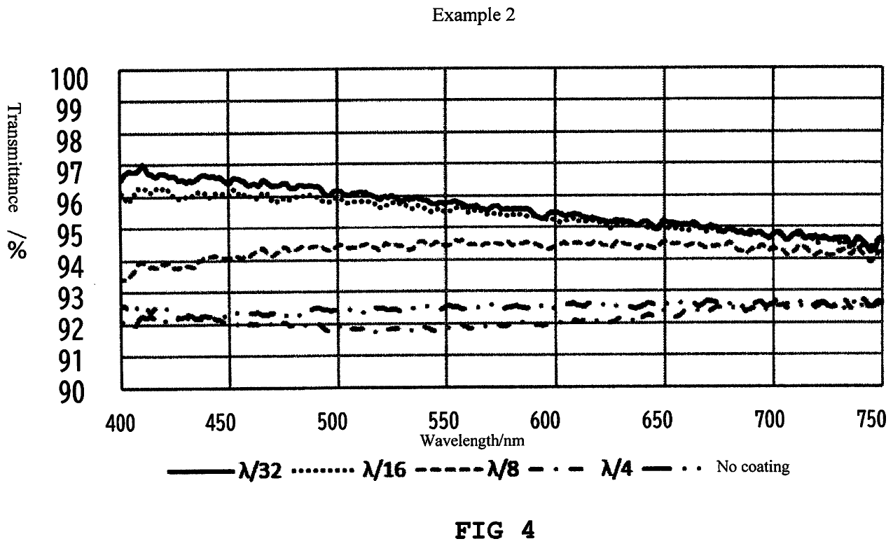

FIG. 4 depicts the spectral characteristics of substrates having fine uneven structures and protective films formed in the steps of Example 2. The steps of Example 2 are a combination of Step A and Step D.

In Step A, a substrate was set in a rack of a vacuum evaporator (dome type: 1600ϕ), the vacuum chamber was evacuated to have an atmospheric pressure of 5×10⁻³(5E−3) Pa within the vacuum chamber, and then ion irradiation was performed.

In Step D, a substrate was set again in a substrate set part of a chemical vapor deposition device, a reaction chamber was evacuated to have an atmospheric pressure of 0.2 Pa within the reaction chamber, hexamethyldisiloxane (HMDS) was subjected to a plasma discharge, and the thus polymerized SiOx film was formed on a substrate surface. Note that in order to proceed to Step D, the vacuum chamber of the vacuum evaporator was opened to remove the substrate, and then the substrate was set again in the chemical vapor deposition device.

In Example 2, with varied optical film thicknesses of SiOx to be deposited on a substrate surface, each sample substrate was irradiated with light having each wavelength between 400 nm and 750 nm, and then the transmission property was measured.

Conditions for the SiOx films were determined in such a manner that the optical film thicknesses were λ/32, λ/16, λ/8, and λ/4, when a light wavelength λ of 550 nm was used for irradiating the substrates. These 4 substrates and those having no SiO₂ deposited thereon (no coating) were used as samples.

As understood from the results of FIG. 4, at each wavelength between 400 nm and 750 nm, each of all substrates having an optical film thickness of λ/32 to λ/4 (λ/32, λ/16, λ/8, λ/4) exhibited a transmittance of about 92% or more, and maintained a high transmittance.

Moreover, it was found that of these 4 substrates, each of substrates having λ/32 to λ/8 (λ/32, λ/16, λ/8) maintained a transmittance of about 94% to 97% with respect to light having each wavelength between 470 nm and 750 nm, and furthermore, each of substrates having λ/32 and λ/16 maintained a transmittance of about 95% or more with respect to light having each wavelength between 470 nm and 750 nm, and had a high anti-reflection effect.

Furthermore, it was found that of these 4 substrates, each of substrates having λ/32 and λ/16 exhibited a high transmittance with respect to light having each wavelength between 470 nm and 750 nm, and tended to exhibit a high transmittance with respect to a wavelength lower than 550 nm.

### (A-3-3) Example 3 (Step C+Step D)

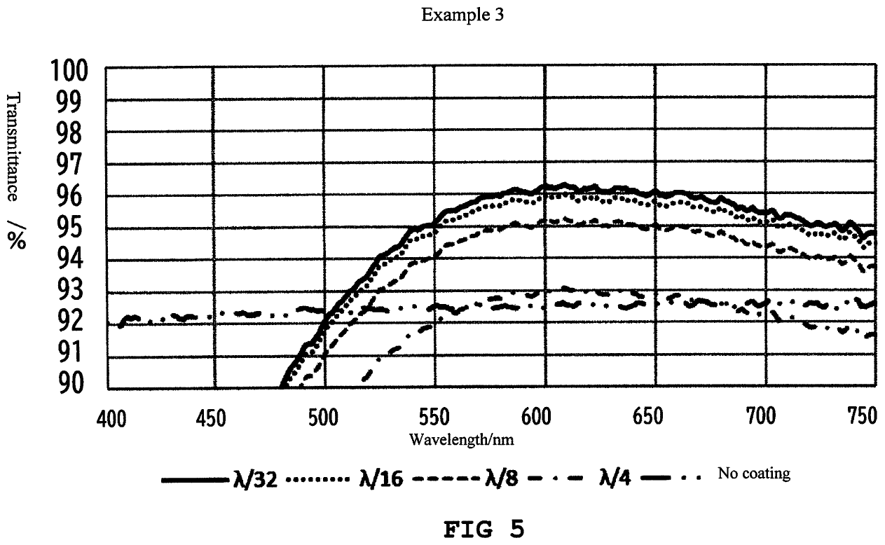

FIG. 5 depicts the spectral characteristics of substrates having fine uneven structures and protective films formed in the steps of Example 3. The steps of Example 3 are a combination of Step C and Step D.

In Step C, a substrate was set in a substrate set part of a chemical vapor deposition device, a reaction chamber was evacuated to have an atmospheric pressure of 0.2 Pa within the reaction chamber, and then a plasma discharge was generated.

In Step D, the chemical vapor deposition device in Step C was used directly, hexamethyldisiloxane (HMDS) was subjected to a plasma discharge without opening the reaction chamber, and the thus polymerized SiOx film was formed on a substrate surface.

In Example 3, with varied optical film thicknesses of SiOx to be deposited on a substrate surface, each sample substrate was irradiated with light having each wavelength between 400 nm and 750 nm and then the transmission property was measured.

Conditions for the SiOx film were determined in such a manner that the optical film thicknesses were λ32, λ/16, λ/8, and λ/4, when a wavelength λ of 550 nm was used for irradiating the substrates. These 4 substrates and those having no SiO₂ deposited thereon (no coating) were used as samples.

As understood from the results of FIG. 5, at each wavelength between 480 nm and 750 nm among wavelengths used for measurement, each of all substrates having optical film thicknesses of λ/32 to λ/4 (λ/32, λ/16, λ/8, λ/4) exhibited a transmittance of about 90% or more, and maintained a high transmittance.

Further, it was found that of these 4 substrates, each of substrates having λ/32 to λ/8 (λ/32, λ/16, λ/8) exhibited a transmittance of about 93% or more at a wavelength of about 520 nm or more, and had a high anti-reflection effect.

### (A-3-4) Example 4 (Step C+Step B)

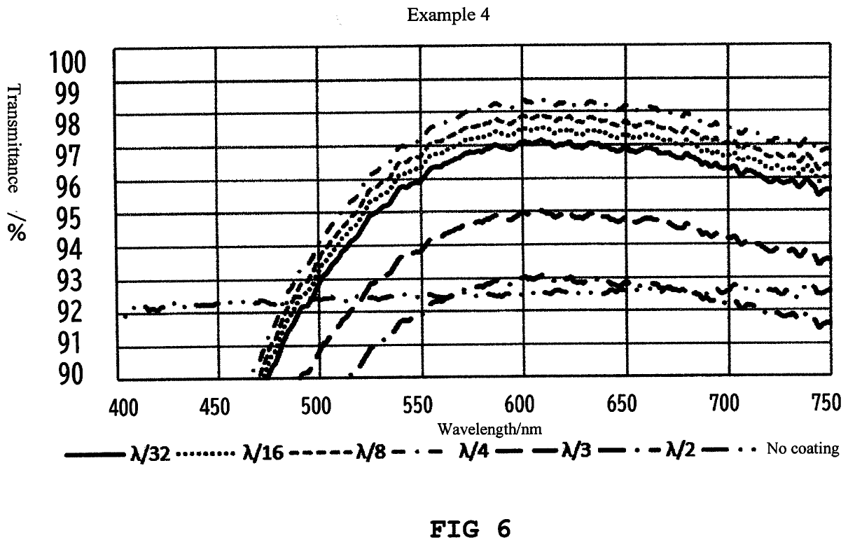

FIG. 6 depicts the spectral characteristics of substrates having fine uneven structures and protective films formed in the steps of Example 4. The steps of Example 4 are a combination of Step C and Step B.

In Step C, a substrate was set in a substrate set part of a chemical vapor deposition device, a reaction chamber was evacuated to have an atmospheric pressure within the reaction chamber of 0.2 Pa, and then a plasma discharge was generated.

In Step B, a substrate was set in a rack of a vacuum evaporator (dome type: 1600ϕ), the vacuum chamber was evacuated to have an atmospheric pressure of 2×10⁻³(2E−3) Pa within the vacuum chamber, and then SiO₂ as a material was evaporated by an electron gun, thereby depositing an SiO₂ film on a surface of the substrate. Note that in order to proceed to Step B, the reaction chamber of the chemical vapor deposition device was opened to remove the substrate, and then the substrate was set again in the vacuum evaporator.

In Example 4, with varied optical film thicknesses of SiO₂ to be deposited on a substrate surface, each sample substrate was irradiated with light having each wavelength between 400 nm and 750 nm, and then the transmission property was measured.

Conditions for the SiO₂ film were determined in such a manner that the optical film thicknesses were λ/32, λ/16, λ/8, λ/4, λ/3, and λ/2, when a wavelength λ of 550 nm was used for irradiating the substrates. These 6 substrates and those having no SiO₂ deposited thereon (no coating) were used as samples.

As understood from the results of FIG. 6, at each wavelength between 470 nm and 750 nm among wavelengths used for measurement, each of all substrates having optical film thicknesses of λ/32 to λ/2 (λ/32, λ/16, λ/8, λ/4, λ/3, λ/2) exhibited a transmittance of about 90% or more, and maintained a high transmittance.

Further, it was found that of these 6 substrates, each of substrates having λ/32 to λ/3 (λ/32, λ/16, λ/8, λ/4, λ/3) exhibited a transmittance of about 93% or more at a wavelength of about 500 nm or more, and had a high anti-reflection effect.

### (A-3-5) Example 5 (Step A+Step B)

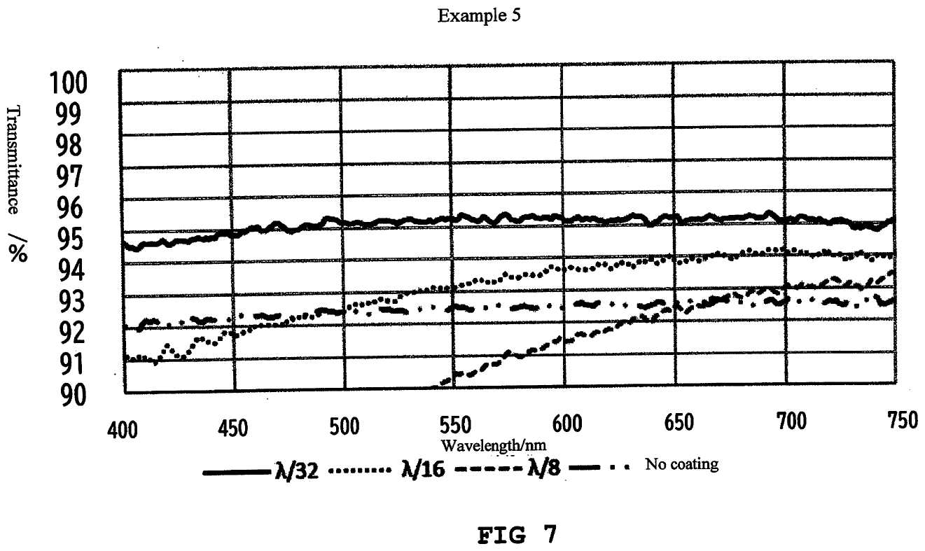

FIG. 7 depicts the spectral characteristics of substrates having fine uneven structures and protective films formed in the steps of Example 5.

The steps of Example 5 are a combination of Step A and Step B, wherein aluminum oxide (Al₂O₃) was used as a material (deposition material) of the protective film.

In Step A, a substrate was set in a rack of a vacuum evaporator, a vacuum chamber was evacuated using a vacuum pump to have an atmospheric pressure of 5×10⁻³(5E−3) Pa within the vacuum chamber, and then ion irradiation was performed. Note that a dome vacuum evaporator with a device diameter (1600¢) was used herein.

In Step B, the vacuum evaporator used in Step A was used. Specifically, Al₂O₃ as a material was evaporated by an electron gun without opening the vacuum chamber, thereby depositing an Al₂O₃ film on a surface of the substrate.

In Example 5, with varied optical film thicknesses of Al₂O₃ on a substrate surface, each sample substrate was irradiated with light having each wavelength between 400 nm and 750 nm, and then the transmission property was measured.

Conditions for the Al₂O₃ film were determined in such a manner that the optical film thicknesses were λ/32, λ/16, and λ/8, when a light wavelength) of 550 nm was used for irradiating the substrates. These 3 substrates and those having no Al₂O₃ deposited thereon (no coating) were used as samples.

As understood from the results of FIG. 7, of these 3 substrates, each of substrates having λ/32 to λ/16 (λ/32, λ/16) exhibited a transmittance of 91% or more with respect to light having each wavelength between 400 nm and 750 nm, and maintained a high transmittance. Particularly, it was understood that of these 3 substrates, the substrate having λ/32 exhibited a transmittance of about 94% or more with respect to light having each wavelength between 400 nm and 750 nm, and maintained a high transmittance.

### (A-3-6) Comparative Example 1 (Step A)

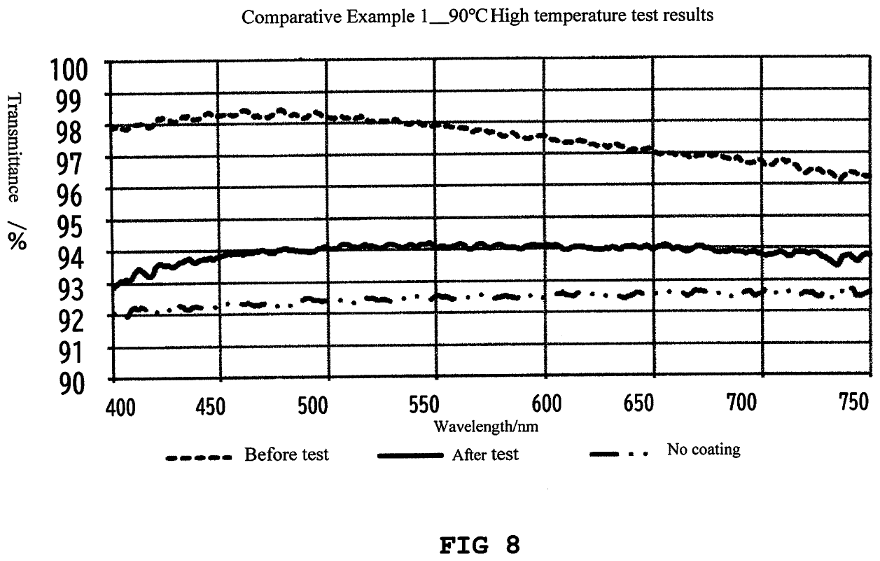

FIG. 8 depicts the results obtained using substrates having fine uneven structures formed in Step A, which are the spectral characteristics of the substrates before a high temperature test, and the spectral characteristics of the substrates under a high temperature environment.

In Comparative Example 1, a fine uneven structure was formed on a substrate surface in Step A, and then the transmission property of the substrate was measured under a high temperature environment for confirmation.

In Step A, a substrate was set in a rack of a vacuum evaporator, a vacuum chamber was evacuated using a vacuum pump to have an atmospheric pressure of 5×10⁻³(5E−3) Pa within the vacuum chamber, and then ion irradiation was performed.

In FIG. 8, a dotted line indicates the results of spectral characteristics of the substrates before the high temperature test, and a solid line indicates the results of the spectral characteristics of the substrates in the high temperature test.

From the results in FIG. 8, at each wavelength between 400 nm and 750 nm, the transmittance of each substrate subjected to the high temperature test was lower than that of the same before the high temperature test. Specifically, it was found that such a fine uneven structure formed on the substrate surface exhibited a decreased transmittance (spectral characteristics) because it had been placed in a high temperature environment.

### (A-3-7) Example 1 High Temperature Test Results of (Step A+Step B)

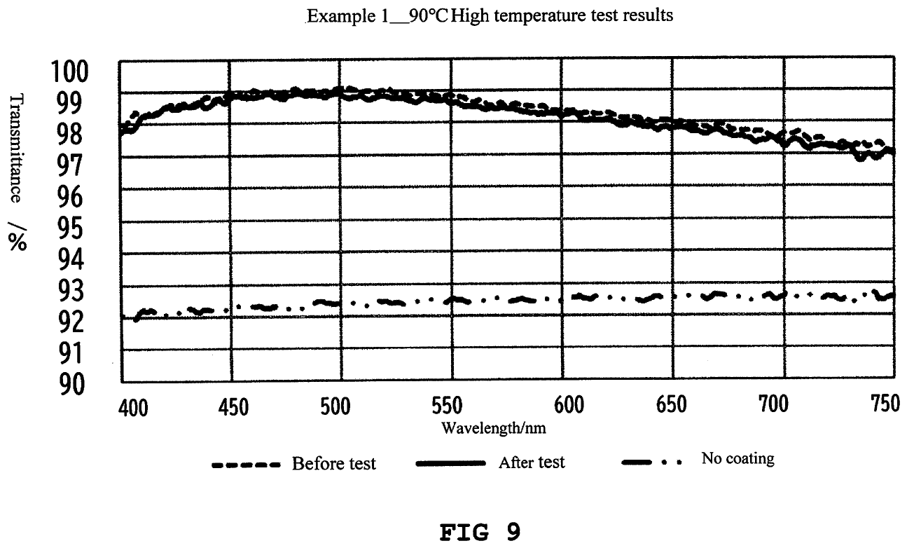

FIG. 9 depicts the results obtained using the substrate of Example 1, which are the spectral characteristics before the high temperature test, and the spectral characteristics under a high temperature environment. Here, the one having an SiO₂ film thickness of λ/8 was used.

As understood from the results in FIG. 9, at each wavelength between 400 nm and 750 nm under a high temperature environment, the substrate after the high temperature test exhibited almost the same transmittance as that of the substrate before the high temperature test. Specifically, it was found that even under a high temperature environment, the transmittance (spectral characteristics) was not decreased, and the substrate had a high anti-reflection effect.

Conventionally, a fine uneven structure on a substrate surface deformed when the temperature reached a high temperature, the anti-reflection effect and the spectral characteristics were lowered (see Comparative Example 1).

In contrast, as in Example 1, an SiO₂ film is formed as a protective film for a fine uneven structure on a substrate surface according to Step B, so that even at a high temperature, the anti-reflection effect and the spectral characteristics can be maintained. In other words, even under a target high temperature environment, the protective film suppresses the deformation of the fine uneven structure, maintaining the anti-reflection effect and the spectral characteristics.

Further, in Example 1, Step A and Step B can be performed successively using the same vacuum evaporator, so that better efficiency for producing optical components can be achieved.

### (A-3-8) Example 3 High Temperature Test Results of (Step C+Step D)

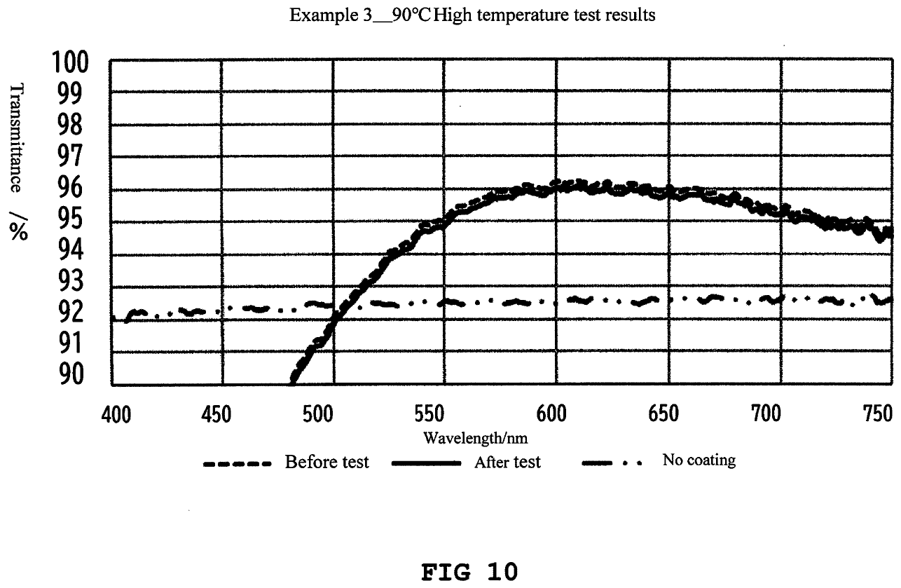

FIG. 10 depicts the results obtained using the substrate of Example 3, which are the spectral characteristics before the high temperature test and the spectral characteristics under a high temperature environment. Here, the substrate having an SiOx film having a film thickness of λ/16 was used.

It was found from the results in FIG. 10, at each wavelength between about 480 nm and 750 nm under a high temperature environment, the substrate after the high temperature test exhibited almost the same transmittance as that of the substrate before high temperature test. Specifically, even under a high temperature environment, it was found that the transmittance (spectral characteristics) was not decreased, and the substrate had a high anti-reflection effect.

Also in the case of Example 3, similarly to the case of (A-3-7), an SiOx film is formed as a protective film for the fine uneven structure on a substrate surface according to Step D, so that the anti-reflection effect and the spectral characteristics can be maintained even at a high temperature. Specifically, even under a target high temperature environment, the protective film suppresses the deformation of the fine uneven structure, maintaining the anti-reflection effect and the spectral characteristics.

Moreover, in Example 3, Step C and Step D can be performed successively using the same chemical vapor deposition device, so that better efficiency for producing optical components can be achieved.

(A-3-9) Comparison with Other Anti-Reflection Films

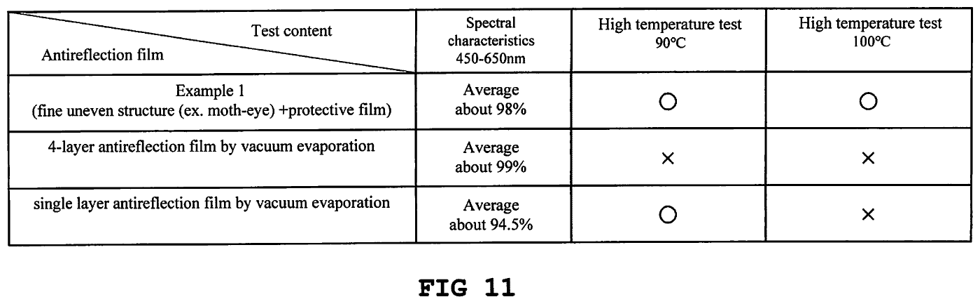

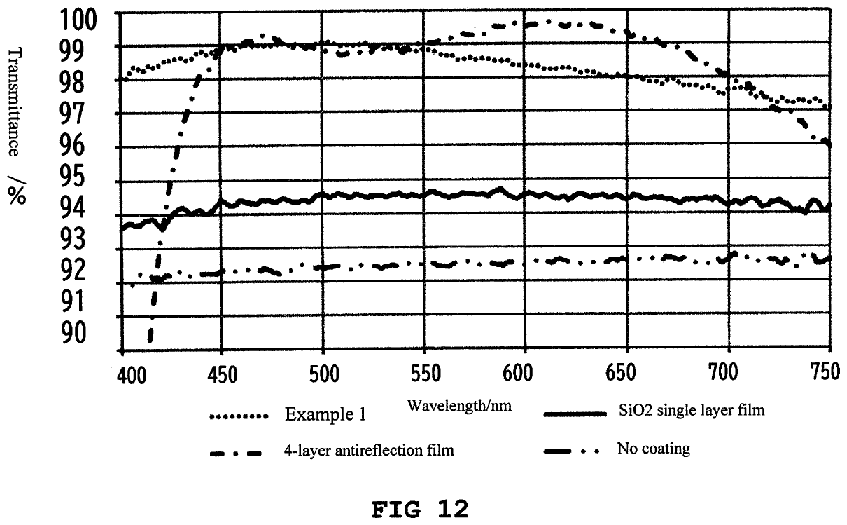

FIG. 11 depicts the results of comparing the anti-reflection effect of Example 1 with that of other anti-reflection films. FIG. 12 depicts the spectral characteristics of Example 1 and those of other anti-reflection films.

As depicted in FIG. 11, there are two examples of other anti-reflection films: “4-layer anti-reflection film produced by vacuum evaporation method”, and “single layer anti-reflection film produced by vacuum evaporation method”.

Further, as depicted in FIG. 11, spectral characteristics of exhibiting the average transmittance between 450 nm and 650 nm, a high temperature test (90° C.), and a high temperature test (100° C.) were the test contents. Note that regarding the spectral characteristics, the results of spectral characteristics in FIG. 12 were used.

The 4-layer anti-reflection film produced by the vacuum evaporation method exhibited the average transmittance of about 99% between 450 nm and 650 nm, and had excellent spectral characteristics. However, microcracks were produced in the high temperature test (90° C.) and the high temperature test (100° C.) required in the optical field of the automotive field, the film appeared “Unacceptable”, and thus was marked “X”.

The single layer film produced by the vacuum evaporation method exhibited no problem in the high temperature test (90° C.), but cracks were produced in the high temperature test (100° C.), and the film was marked “X”.

From the results in FIG. 9, Example 1 exhibited the average transmittance of about 98% or more between 450 nm and 650 nm. Furthermore, the substrate of Example 1 exhibited no change and showed excellent results in both the high temperature test and the high-temperature high-humidity test. The substrate of Example 1 was manufactured using the same device, can be manufactured successively, and mass productivity can be expected.

### (A-4) Results of Embodiment

As described above, according to the embodiment, a protective film is formed on a fine uneven structure formed on a surface of a synthetic resin substrate, and thus an optical component having a high anti-reflection effect under a high temperature environment can be manufactured.

1-8. (canceled)

9. A method for producing an optical component, comprising:
a fine uneven structure forming step of changing a surface of a synthetic resin substrate by ion irradiation, so as to form a fine uneven structure on the surface of the substrate; and
a protective film forming step of evaporating and depositing a deposition material on the surface of the substrate, so as to form a protective film that suppresses a collapse of the fine uneven structure formed on the surface of the substrate in a high-temperature environment, wherein
the fine uneven structure forming step comprises discharging plasma in a depressurized container for ion irradiation in the plasma atmosphere, so as to cleave the chain bonds of the substrate and form the fine uneven structure on a surface of the substrate,
the protective film forming step comprises, in the same container as that of the fine uneven structure forming step, adhering a silicon oxide on the surface of the substrate by vacuum evaporation using the silicon oxide as the deposition material, so as to form a silicon oxide film on the fine uneven structure on the surface of the substrate, and
a transmittance at a wavelength around 550 nm under the high-temperature environment of 90° C. to 100° C. is 95% or more.

10. The method for producing an optical component according to claim 1, wherein in the protective film forming step, when irradiation is performed at a wavelength of 550 nm, the silicon oxide film has an optical film thickness of λ/50 to λ/4.
